(19) United States
(12) Patent Application Publication
(10) Pub. No.: US 2013/0112272 A1
(43) Pub. Date: May 9, 2013

(54) WEATHERING-RESISTANT BACKING FILMS

(71) Applicants: Jochen Ackermann, Muehltal (DE); Florian Schwager, Muenster (DE)

(72) Inventors: Jochen Ackermann, Muehltal (DE); Florian Schwager, Muenster (DE)

(73) Assignee: EVONIK RÖHM GmbH, Darmstadt (DE)

(21) Appl. No.: 13/810,725

(22) PCT Filed: May 31, 2011
(86) PCT No.: PCT/EP2011/058880

§ 371 Date: Jan. 17, 2013

(30) Foreign Application Priority Data
Jul. 22, 2010 (DE) 10 2010 038 292.2

(51) Int. Cl. H01L 31/048

(52) U.S. Cl. CPC H01L 31/0487
USPC 136/259; 428/220; 428/339; 428/215; 427/248.1; 156/60; 156/150; 204/192.15

(57) ABSTRACT

The invention relates to the use of non-transparent, methacrylate-containing one-, two- or multi-layered films in flexible photovoltaic systems, and to the production of said films by extrusion coating, extrusion lamination (adhesive lamination, melt lamination or hotmelt lamination) or glue lamination. For this purpose, e.g. a thin, inorganic or metallically coated film, for example made of PET, is laminated or coextruded with a weather-resistant film, e.g. a film made of PMMA or PMMA polyolefin coextrudate. In particular, laminates are produced in which at least one of the two layers is non-transparent. An optional inorganic oxide or metal layer has the property of a high barrier effect against water vapour and oxygen while the PMMA layer exhibits weather resistance stability.

### FIELD OF THE INVENTION

The invention relates to the use of non-transparent, methacrylate-containing one-, two- or multi-layer films in flexible photovoltaic systems, and also to the production of these films by extrusion coating, extrusion lamination (adhesive, melt or hotmelt lamination) or adhesive lamination.

For these purposes, for example, a thin, inorganically coated film, of PET, for example, is laminated or coextruded with a weathering-resistant film, of PMMA or PMMA-polyolefin coextrudate, for example. Produced more particularly are laminates in which at least one of the two layers is not transparent.

An optional inorganic oxide layer or metal layer has the property of a high barrier effect to water vapour and oxygen, while the PMMA layer contributes the weathering stability.

### PRIOR ART

Modern photovoltaic modules, especially flexible photovoltaic modules, now have very thin designs and a particularly high transparency. These photovoltaic modules generally comprise multi-layer film and/or plate laminates. Such laminates can be found, for example, in the patent application with the application no. DE 102009003223.1, filed at the German Patent and Trademark Office on 19 May 2009.

In these systems there are film laminates both on the front, i.e. between radiation source and semiconductor layer, and on the back, to protect the semiconductor layer. Individual laminates of this kind are described in, for example, the patent application with the application number DE 102009000450.5, filed at the German Patent and Trademark Office on 28 Jan. 2009. A disadvantage of particularly thin transparent systems of this kind, which in the best case also include a very thin semiconductor layer, is a reduced energy yield. Some of the electromagnetic radiation penetrates the laminate completely and can therefore not be utilized for energy production.

Corresponding protective films with a mirror layer, of silver, for example, are known from photothermal systems. Mirror layers of this kind reflect the light specifically in the direction of the incident beam. Consequently, the beam passes twice, perpendicularly, through the photoactive semiconductor layer. Although this does improve the energy yield, it is not optimal.

One particularly important aspect of the films for photovoltaic applications is the weathering resistance and hence the protection against adverse effects of UV radiation, temperature fluctuations or atmospheric humidity. Depending on the design of the systems, this is also very important in any aspect for the backs of the photovoltaic systems. UV protection, furthermore, plays a large part particularly in the case of very thin, flexible systems with a relevant light transmissibility. Hence the back of a photovoltaic system may well be damaged solely by the penetrating UV radiation, in long-term applications.

Weathering-resistant, transparent and high-impact films based on polymethacrylate are sold by the applicant under the name PLEXIGLAS®. Patent DE 38 42 796 A1 describes the production of a clear, high-impact, acrylate-based moulding composition, films and mouldings produced from it, and a process for producing the moulding composition. An advantage of these films is that they do not discolour and/or embrittle under heat and humidity exposure. Furthermore, they avoid the phenomenon known as stress whitening under impact or flexural stress. These films are transparent and also remain so on exposure to heat and humidity, on weathering, and on impact or flexural stress.

The processing of the moulding composition to give the stated transparent, high-impact films is accomplished ideally by extrusion of the melt through a slot die and calendering on a roll mill. Films of this kind feature long-term clarity, insensitivity to heat and cold, weathering stability, low yellowing and embrittlement, and low stress whitening on creasing or folding, and are therefore suitable, for example, as windows in tarpaulins, car covers or sails. Such films have a thickness below 1 mm, for example 0.02 mm to 0.5 mm. One important area of application lies in the formation of thin surface layers with a thickness, for example, of 0.02 mm to 0.5 mm on rigid, dimensionally stable base structures, such as metal sheets, boards, chipboard panels, plastics boards and the like. For the production of such coatings there are a variety of methods available. Thus, the film may be extruded to a moulding composition, calendered and laminated onto the substrate. Through the technique of extrusion coating, an extruded strand can be applied to the surface of the substrate and calendered by means of a roll. If a thermoplastic is used as the substrate itself, the possibility exists of coextruding both compositions to form a surface layer comprising the clear moulding composition of the invention.

The barrier properties of PMMA films with respect to water vapour and oxygen, however, are inadequate, but such properties are necessary for medical applications, for applications in the packaging industry, but especially in electrical applications involving outdoor use.

In order to improve the barrier properties, either metallic layers or, if high light transmission is required, transparent inorganic layers are applied to polymer films. Layers of silicon oxide and of aluminium oxide have become established in particular. This inorganic oxide layer (SiOₓ or AlOₓ) is applied in a vacuum coating method (chemically, JP-A-10025357, JP-A-07074378; thermal or electron-beam evaporation, sputtering, EP 1 018 166 B1, JP 2000-307136 A, WO 2005-029601 A2). In EP 1018166 B1 it is said that the UV absorption of the SiOx layer can be influenced by the ratio of silicon to oxygen in the SiOx layer. This is important in order to protect underlying layers from the UV radiation. The disadvantage, however, is that altering the ratio of silicon to oxygen also alters the barrier property. It is therefore not possible to vary transparency and barrier effect in isolation from one another.

The inorganic oxide layer is occasionally applied primarily to polyesters and polyolefins, since these materials withstand the temperature stress during the evaporating process. Moreover, the inorganic oxide layer adheres well to polyesters and polyolefins, the latter being subjected to corona treatment prior to coating. Since, however, these materials are not stable towards weathering, they are often laminated with halogenated films, as described in WO 94/29106, for example. Halogenated films, however, are problematic on environmental grounds.

As is known from U. Moosheimer, Galvanotechnik 90 No. 9, 1999, pp. 2526-2531, the coating of PMMA with an inorganic oxide layer does not improve the barrier effect towards water vapour and oxygen, since PMMA is amorphous. Unlike polyesters and polyolefins, however, PMMA is stable towards weathering.

The applicant, in DE 102009000450.5, uses coating materials which produce good adhesion between the inorganic layer and the adhesion promoter. As is known to the skilled person, the adhesion between organic and inorganic layers is more difficult to achieve than between layers of the same kind.

According to the prior art, there are also known backing films for photovoltaic systems that are intended to improve the weathering stability. In EP 1 956 660, for instance, there is a film laminate comprising a polyester layer and a polypropylene layer. Although this laminate certainly improves the hydrolysis resistance and hence the moisture resistance of photovoltaic systems, there is no improvement to the efficiency or to the UV resistance of the back. WO 2009/124098 describes microstructured backing films for improved heat removal. As compared with the prior art, however, the weathering stability of these backing films is poorer, and there is virtually no improvement in the efficiency of the photoactive layer.

EP 2 124 261 describes backing films in the form of PET films filled with titanium dioxide or carbon black. These fillers are added to the films for additional UV protection. EP 2 124 261, however, does not teach any improvement in efficiency.

### Problem

The problem addressed by the present invention was that of providing an innovative, flexible photovoltaic system which allows an improvement in energy yield over the prior art and has a long life even under extreme weathering conditions.

The object of the invention, therefore, was to provide a barrier film, for producing such flexible photovoltaic systems, that is stable towards weathering, with an assurance of high barrier properties towards water vapour and oxygen.

A further object was that of reducing the overall light transmissibility of flexible photovoltaic systems by means of an innovative barrier film.

A further intention was to achieve, by means of this combination of materials, a partial discharge voltage of greater than 1000 V.

### Solution

The problem is solved by a multi-layer, non-transparent barrier film which comprises at least one weathering-stable layer, comprising at least one polymethacrylate, and a refracting filler. In particular, said barrier film comprises a backing film in a photovoltaic module, especially in a flexible photovoltaic system. The properties are achieved through a multi-layer film where the individual layers are combined with one another by vacuum vapour coating, lamination, extrusion lamination (adhesive, melt or hotmelt lamination), or extrusion coating. Customary methods can be used for this, as described in, for example, S. E. M. Selke, J. D. Culter, R. J. Hernandez, “Plastics Packaging”, 2nd edition, Hanser-Verlag, ISBN 1-56990-372-7 on pages 226 and 227.

In one advantageous embodiment, the object is achieved by an innovative, non-transparent backing film for photovoltaic modules that is composed at least of the following layers:
a) a weathering-stable protective layer comprising at least one polymethacrylate,
b) an optional adhesive layer,
c) an optional barrier layer,
d) a support film.

The non-transparency is brought about in this context by means of fillers or filler mixtures which are comprised in at least one of the layers a), b) or d). The fillers are preferably comprised in the weathering-stable protective layer or in the support film, more preferably in the support film. However, the fillers may also be comprised in the optional layer of adhesive or in more than one layer through to all three layers. In the individual layers in this case there may be different fillers or filler mixtures.

The backing film, from outside to inside, is at least composed of a protective layer, an optional adhesive layer, a barrier layer and a support film. The protective layer in the backing film is preferably a PMMA film, a PMMA-PVDF blend film, a film composed of a coextrudate of PMMA and a polyolefin or polyester, or a PMMA-PVDF, PMMA-polyolefin or a PMMA-PET two-layer film. The barrier layer is composed predominantly of an inorganic oxide or of a metal layer. The support film is preferably a polyester or polyolefin film. The fillers are organic or inorganic fillers which are sufficiently large to refract or reflect the light.

The backing film of the invention is composed more particularly of a support film having a thickness of between 10 μm and 10 cm, preferably between 50 μm and 10 mm and more preferably between 100 and 400 μm, an adhesive layer having a thickness of between 1 and 100 μm, preferably between 50 and 50 μm, and a protective layer having a thickness of between 10 μm and 10 cm, preferably between 20 μm and 10 mm and preferably between 50 and 400 μm.

The backing films of the invention for solar systems are preferably but need not necessarily be used only in flexible solar films, but may also be used in rigid photovoltaic systems of the kind that are well-known prior art. In such cases, where the support film and/or the protective layer may each have a thickness of up to 10 cm, the term “backing film” is synonymous with a backing plate with virtually no flexibility.

The backing films of the invention are located in photovoltaic systems, irrespective of their specific design and of whether they are rigid or flexible, on the back of the photoactive semiconductor layer. The support film faces the semiconductor layer, and the protective layer constitutes the outside. In this preferred embodiment, the support film is preferably filled with the filler. The primary function of the support film in the construction is to reflect and scatter radiation that penetrates the preceding layers—including the semiconductor layer—in such a way that the semiconductor layer is penetrated a second time. The scattering which occurs, in contrast to a mirror film, has the great advantage that the radiation is scattered not perpendicularly, and hence reflected on the shortest path back through the semiconductor layer, but instead into the semiconductor layer, via longer paths. In this way it is possible to achieve significantly higher efficiencies for, in particular, very thin photovoltaic systems which are therefore partly radiation transmissive.

The backing film of the invention is applied either directly to the semiconductor layer or else to a metallic or polymeric protective layer that is applied additionally on the back of the semiconductor layer. This is accomplished usually by means of adhesive bonding, as for example with layer2 of adhesive.

The protective layer, more particularly the PMMA protective layer, fulfils the property of weathering stability; the support film leads to stability on the part of the laminate. Since direct inorganic coating of PMMA is not possible according to the prior art, the support film is needed, furthermore, in order to ensure a long-lived and firm bond to the barrier laminate, which optionally carries an inorganic layer on the surface. The PMMA layer, in turn, protects the polyester or polyolefin support film from effects of weathering.

Furthermore, the function of protection from UV radiation is no longer to be undertaken, as in the prior art, by the inorganic oxide layer, but instead by the PMMA layer. Accordingly, the oxide layer can be optimized exclusively according to optical criteria. Depending on the construction of the photovoltaic system, UV protection may be very advantageous especially for the back of the system; accordingly, a great advantage is produced by the PMMA-containing backing films used in accordance with the invention.

### DETAILED DESCRIPTION

### Advantages of the Invention

The backing film of the invention is particularly stable towards weathering.
The backing film of the invention possesses a high barrier effect with respect to water vapour and oxygen (<0.05 g/(m² d), and for metal layers even <0.0001 g/(m² d)).
The backing film of the invention protects underlying layers from UV radiation, irrespective of the composition of the SiOₓ layers.
The backing film of the invention can be produced inexpensively, since a thin film can be used for the discontinuous process of inorganic vacuum vapour coating.
The backing film of the invention can be produced easily, since it is necessary only to join inorganic to inorganic layers and organic to organic layers.
The backing film of the invention has a partial discharge voltage of at least 1000 V and a transparency of less than 10% in the wavelength range of 300 nm-1200 nm.

### The PMMA Protective Layer

As polymethacrylate-containing protective layer and hence as outermost layer of the first laminate, use is made of films comprising preferably polymethyl methacrylate (PMMA) or impact-modified PMMA (im-PMMA). Coextrudates of polymethacrylates and polyolefins or polyesters may also be used. In that case, coextrudates of polypropylene and PMMA are preferred. Alternatively, besides PMMA films, it is also possible for PVDF/PMMA two-layer films or films of PVDF/PMMA blends to be used as protective layer.

In one particular embodiment it is also possible to use a two-layer film of PMMA and a polyolefin, preferably polypropylene, or of PMMA and PET. These two-layer films also comprise systems composed of a PET or polyolefin layer and a blend or coextrudate of PMMA and PVDF.

The two-layer films can be produced by means of film coextrusion or by lamination. In the case of a laminate, the two-layer films are joined to one another with an adhesive. The choice of an adhesive (layer3 of adhesive) is dependent on the substrates to be bonded to one another and on exacting requirements imposed on the transparency of the layer of adhesive. For the combination of PMMA and PET, melt adhesives are preferred. Examples of such melt adhesives are ethylene-vinyl acetate hotmelts (EVA hotmelts) or acrylate-ethylene hotmelts. Acrylate-ethylene hotmelts are preferred. The layer3 of adhesive generally has a thickness of between 10 and 100 μm, preferably between 20 and 80 μm and more preferably between 40 and 70 μm.

It is the case for all two-layer films that the filler present in accordance with the invention in the backing film may be comprised in one of the two layers or even in both layers of the two-layer polyolefin-PMMA, PET-PMMA or PVDF-PMMA film. Where the two-layer film is joined to a filler-containing support film, however, it is also possible for neither of the two layers to comprise a filler.

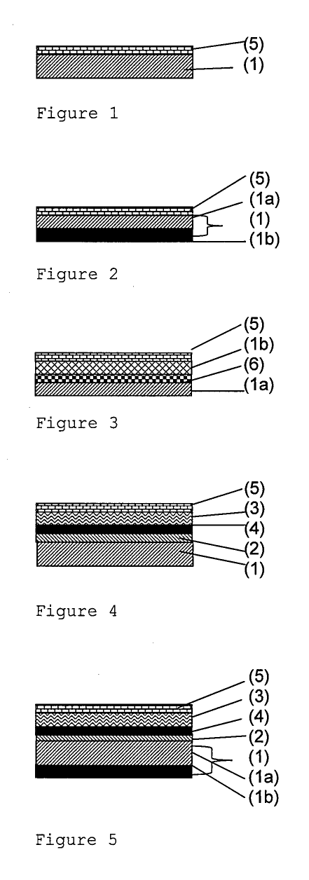

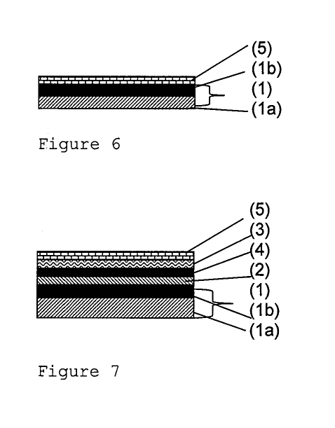

In the case of a PVDF-PMMA two-layer film, the PVDF layer is located preferably on the outside of the two-layer film (see FIGS. 2 and 5). Accordingly, the good properties, of dirt repellency, for example, of the PVDF are additionally employed. In the case of polyolefin-PMMA or PET-PMMA two-layer films, the PMMA layer is preferably on the outside of the two-layer film and hence of the backing film (see FIGS. 6 and 7).

In one alternative embodiment, instead of the PMMA, the polymethacrylate may also comprise a polymethacrylimide (PMMI). Furthermore, it may also comprise a blend or a coextrudate of PMMI with PMMA and/or PVDF.

The protective layer has a thickness of 10 μm to 10 cm; preferably the thickness is 20 μm to 10 mm, and very preferably 50 μm to 1000 μm. At thicknesses more than 1000 μm, the films are no longer flexible, and the reference may also be to PMMA plates.

The composition of suitable impact-modified poly(meth)acrylate plastics can be found in EP 1 963 415. The impact modifiers for polymethacrylate plastics that are used therein are described in, for example, EP 0 113 924, EP 0 522 351, EP 0 465 049, and EP 0 683 028, preferably in EP 0 528 196.

In accordance with the invention, light stabilizers may be added to the support film. By light stabilizers are meant UV absorbers, UV stabilizers and free-radical scavengers.

Examples of UV absorbers are derivatives of benzophenone, for example, whose substituents, such as hydroxyl groups and/or alkoxy groups, are located usually in positions 2 and/or 4. Also very suitable as UV absorbers are substituted benzotriazoles. It is also possible, furthermore, to use a UV absorber from the class of the 2-(2′-hydroxyphenyl)-1,3,5-triazines. Specific examples of the individual groups of UV absorbers are also found in EP 1 963 415.

UV absorbers that can additionally be used are ethyl 2-cyano-3,3-diphenylacrylate, 2-ethoxy-2′-ethyloxalic bisanilide, 2-ethoxy-5-tert-butyl-2′-ethyloxalic bisanilide and substituted benzoic acid phenyl esters.

The UV absorbers may be present in the form of low molecular compounds, as indicated above, in the polymer compositions to be stabilized. It is, however, also possible for UV-absorbing groups to be bonded covalently in the matrix polymer molecules, after copolymerization with polymerizable UV absorption compounds, such as acrylic, methacrylic or allyl derivatives of benzophenone derivatives or benzotriazole derivatives, for example. The fraction of UV absorber, which may also comprise mixtures of chemically different UV absorbers, is generally 0% to 10% by weight, especially up to 5% by weight, more particularly up to 2% by weight, based on the polymer. In the case of a multi-layer polymer film, the UV absorber is preferably in the PMMA layer, but may also be present in the PVDF, polyolefin and/or polyester layer.

Examples of free-radical scavengers/UV stabilizers here include sterically hindered amines, which are known under the name HALS (Hindered Amine Light Stabilizers). They can be used for inhibiting ageing processes in coatings and plastics, especially in polyolefin plastics (Kunststoffe, (1984) 10, pp. 620 to 623; Farbe+Lack, Volume 96, 9/1990, pp. 689 to 693). Responsible for the stabilizing effect of the HALS compounds is the tetramethylpiperidine group they contain. This class of compound may be either unsubstituted or substituted by alkyl or acyl groups on the piperidine nitrogen. The sterically hindered amines do not absorb in the UV range. They scavenge free radicals that are formed, something which the UV absorbers are themselves unable to do.

Examples of HALS compounds with a stabilizing action, which may also be employed as mixtures, include the following: bis(2,2,6,6-tetramethyl-4-piperidyl) sebacate, 8-acetyl-3-dodecyl-7,7,9,9-tetramethyl-1,3-8-triazaspiro[4.5]decane-2,5-dione, bis(2,2,6,6-tetramethyl-4-piperidyl) succinate, poly(N-β-hydroxyethyl-2,2,6,6-tetramethyl-4-hydroxy-piperidine-succinic esters) or bis(N-methyl-2,2,6,6-tetramethyl-4-piperidyl) sebacate. Particularly preferred UV absorbers are, for example, Tinuvin® 234, Tinuvin® 360, Chimasorb® 119 or Irganox® 1076.

In the polymer mixtures of the invention, the free-radical scavengers/UV stabilizers are employed in amounts of 0% to 15% by weight, especially amounts of up to 10% by weight, more particularly in amounts of up to 5% by weight, based on the polymer. In the case of a multi-layer polymer film, the UV absorber is preferably in the PMMA layer, but may also be present in the PVDF, polyolefin and/or polyester layer.

The outside of the protective layer may additionally be coated. For example, the protective layer may have a scratch-resistant coating. In the context of this invention, the term “scratch-resistant coating” is understood to be a collective term for coatings which are applied for the purpose of reducing surface marring and/or for improving the abrasion resistance. For the use of the film laminates in photovoltaic systems, for example, a high abrasion resistance in particular is of great importance. A further important property of the scratch-resistant coating in the widest sense is that this layer does not adversely alter the optical properties of the film assembly. As scratch-resistant coatings it is possible to use polysiloxanes, such as CRYSTALCOAT™ MP-100 from SDC Techologies Inc., or AS 400-SHP 401 or UVHC3000K, both from Momentive Performance Materials. These coating formulations are applied to the surface of the film assembly or of the outer film by—for example—roll coating, knife coating or flow coating. Examples of further coating technologies contemplated include PVD plasma (physical vapour deposition; physical gas-phase deposition) and also CVD plasma (chemical vapour deposition; chemical gas-phase deposition).

Additionally it is possible for anti-soiling coatings, which are general knowledge to the skilled person, to be applied to the film.

### The Support Film

The support films are, as described above, an optional constituent of the backing films of the invention. As a support film it is preferred to use films made preferably of polyesters (PET, PET-G, PEN) or polyolefins (PE, PP). The choice of support film is determined by the following mandatory properties: the film must be flexible and resistant to heat distortion. Films which have proven in particular to have this kind of profile of properties include polyester films, especially coextruded, biaxially oriented polyethylene terephthalate (PET) films.

The support film has a thickness of between 10 μm and 10 cm; the thickness is preferably between 50 μm and 10 mm, and very preferably between 100 and 1000 μm. In the case of films that are no longer flexible, examples being those having a thickness of more than 1000 μm, they may also be referred to as support plates.

### The Fillers

The fillers used in accordance with the invention, which may also take the form of a mixture of different fillers, are organic or inorganic fillers whose use in polymer matrices is known. These fillers not only have the aforementioned function of scattering and/or reflecting the radiation, particularly the radiation in the wavelength range that is of interest for photovoltaic applications, between 380 nm and 1200 nm, but also, furthermore, make a positive contribution to the gas barrier properties, especially with respect to oxygen or water vapour, of the backing film. As a result, this film, if necessary or desired, can be made significantly thinner.

Suitable fillers are all materials which are known, for example, from the plastics industry. Described in the prior art, for example, as already stated, are titanium dioxide or carbon black. In order to achieve the objective of increased efficiency of photovoltaic systems, however, it has been found that particular suitability is possessed by fillers which are, in particular, pale in colour, more precisely white, and which therefore reflect in a broad light spectrum. These fillers may be organic or inorganic in nature.

Examples of particularly suitable organic fillers are, in particular, elastomer particles or thermoplastics which are not miscible in the matrix.

The inorganic fillers are, for example, natural silicates, such as talc, mica or siliceous earth, carbonates, such as chalk, sulphates, oxides, such as finely ground quartz, or calcium oxide or zinc oxide, or hydroxides, such as crystalline silica, aluminium hydroxide or magnesium hydroxide.

Synthetic inorganic fillers may be, for example, precipitated silica, fumed silica, chalk, titanium dioxide, calcium carbonate, aluminium hydroxides or magnesium hydroxides, or glass.

The fillers may be added to the respective material for forming the support film, adhesive layer or protective layer prior to processing. Alternatively, and especially in relation to the support film, use may be made of commercially available filled films, of PET or PP, for example. Examples thereof are films of Moplen EP440G from LyondellBasell or Hostaphan® WO D027 from Mitsubishi Polyester Film.

A filled support film contains between 1.0% and 50% by weight, preferably between 1.0% and 30% by weight, of filler. The same value limits apply in respect of the adhesive layer or the protective layer as well.

### The Barrier Layer

The barrier layer is applied to the support film and is composed preferably of inorganic oxides, for example SiOₓ or AlOₓ. However, use may also be made of other inorganic materials (for example SiN, SiNₓO_{y}, ZrO, TiO₂, ZnO, FeₓO_{y}, transparent organometallic compounds). As SiOₓ layers it is preferred to use layers having an x value of 1 to 2, preferably of 1.3 to 1.7. The layer thickness is 5 nm-300 nm, preferably 10 nm-100 nm, more preferably 20 nm-80 nm.

For x in the case of AlOₓ the range is from 0.5 to 1.5; preferably from 1 to 1.5 and very preferably from 1.2 to 1.5 (where x=1.5 Al₂O₃).

The layer thickness is 5 nm-300 nm, preferably 10 nm-100 nm, more preferably 20 nm-80 nm.

The inorganic oxides may be applied by means of physical vacuum deposition (electron-beam or thermal process) magnetron sputtering or chemical vacuum deposition. This may take place reactively (with supply of oxygen) or non-reactively. Flame, plasma or corona pretreatment is likewise possible.

Alternatively the barrier layer may also be realized as a metal film. This may be, for example, a copper, silver or aluminium film, preferably an aluminium film. A metal later of this kind may be applied to the support film in any of a variety of ways. For instance, a metal foil may be adhered, or the support film may be extruded on to a metal foil. An alternative possibility as well is to apply a metal layer by sputtering or via a vacuum method to the support film.

Metal films have the advantages over oxide layers not only of being generally less costly and of exhibiting a significantly better barrier effect. Metal films additionally bring reflection of the radiation that penetrates the photovoltaic system. This radiation is additionally scattered in the filler-containing layer situated above, and so through this combination of materials it is possible to achieve a further increase in the energy yield, and in the efficiency. This is of interest in particular for very thin photovoltaic systems. The layer thickness of the metal film is 5 nm to 300 nm, preferably 10 nm to 100 nm.

If a metal film is used, the filler must of course be in a layer between the layer2 of adhesive, which joins the backing film to the substrate, and the metal film. Accordingly, the filler must be comprised in the support film.

### The Layer of Adhesive

The layer of adhesive is situated between protective layer and barrier layer. It allows adhesion between the two layers. The layer of adhesive has a thickness of 1 to 100 μm, preferably of 2 to 50 μm, more preferably of 5 to 20 μm.

The layer of adhesive may be formed from a coating formulation which is subsequently cured. This is done preferably by UV radiation, but may also take place thermally. The layer of adhesive contains 1%-80% by weight of polyfunctional methacrylates or acrylates or mixtures thereof as main component. It is preferred to use polyfunctional acrylates, e.g. hexanediol dimethacrylate. In order to increase the flexibility it is possible to add monofunctional acrylates or methacrylates, examples being hydroxyethyl methacrylate or lauryl methacrylate. The layer of adhesive further comprises, optionally, a component which improves the adhesion to SiOx, examples being acrylates or methacrylates that contain siloxane groups, e.g. methacryloyloxypropyltrimethoxysilane. The acrylates or methacrylates containing siloxane groups may be present at 0%-48% by weight in the layer of adhesive. The layer of adhesive comprises 0.1%-10% by weight, preferably 0.5%-5% by weight, more preferably 1%-3%, of initiator, e.g. Irgacure® 184 or Irgacure® 651. As chain transfer agents, the layer of adhesive may also comprise 0%-10% by weight, preferably 0.1%-10% by weight, more preferably 0.5%-5%, of sulphur compounds. One variant is to replace some of the main component by 0%-30% by weight of prepolymer. The adhesive component optionally comprises 0%-40% by weight of additives which are customary for adhesives.

The layer of adhesive is preferably formed of a melt adhesive. This adhesive may consist of polyamides, polyolefins, thermoplastic elastomers (polyester, polyurethane or copolyamide elastomers) or of copolymers. Preference is given to using ethylene-vinyl acetate copolymers or ethylene-acrylate copolymers or ethylene-methacrylate copolymers. The layer of adhesive may be applied by means of roll application methods in the laminating procedure or by means of a nozzle in the extrusion laminating procedure or in the extrusion coating procedure.

### Adhesive Layer2

The film laminate may be adhered to a substrate by means of a further adhesive layer of adhesive2, which is applied to the bottom, i.e. to the side facing away from the protective layer. The substrate may comprise, for example, a semiconductor such as silicon. The adhesive in this case may be a hotmelt, such as an ethylene-vinyl acetate EVA, for example. The hotmelt layers generally have a thickness of between 100 and 200 μm.

### Processes

For producing the backing films of the invention there are various alternative production methods:

In the simplest embodiment, the protective film is provided with the filler in the course of production. In the case of a two-layer film, the film is produced by lamination, coextrusion or film lamination. In this case at least one layer is given the filler.

In the case of a laminate of protective layer and support film, there are different production alternatives. In this particular embodiment with particularly strong barrier effect, the polymer film, the subsequent support film, is coated inorganically on both sides.

a) A polymer film, the subsequent support film, is coated inorganically or one or both sides by means of vacuum evaporation or sputtering, and is then combined with the protective layer by means of lamination, extrusion lamination or extrusion coating. In this case at least one of the three layers is filled with filler.

b) A polymer film, the subsequent support film, is coated inorganically on one or both sides by means of vacuum evaporation or sputtering, and this film is joined by means of a layer of adhesive to the protective layer, which is used in the form of a film. In this case at least one of the three layers is filled with filler.

c) For the physical vacuum evaporation specified in a) or b), silicon oxide or aluminium oxide is evaporated by means of electron beam.

d) Alternatively, in the physical vacuum evaporation specified in a) or b), silicon oxide or aluminium oxide is evaporated thermally.

Since the direct inorganic coating of PMMA is not possible according to the prior art, the support film, hence a polyester film or polyolefin film, is vapour-coated with the inorganic layer, and laminated or extrusion-laminated to the protective layer, a PMMA film, for example. The PMMA layer protects the polyester or polyolefin film from the effects of weathering. The adhesion between the inorganic layer and the PMMA layer is produced by means of an adhesive, an example being a UV-curable acrylate adhesive containing siloxane groups. The use of a melt adhesive is likewise possible. The PMMA layer further preferably comprises a UV absorber, which protects the polyester or polyolefin film from UV radiation. Alternatively, the UV absorber may be present in the polyester or polyolefin layer.

For the particularly preferred embodiment of a metal film, production may take place alternatively to sections a) to d). Alternatively, the metal film may also be used in the form of a metal foil, such as an aluminium foil, for example, and may be produced with the support film by lamination or extrusion of the support film material on to the metal foil.

Lastly, the completed backing film is bonded to the substrate, generally to the semiconductor.

### Applications

These barrier films are used, in accordance with the invention, in organic photovoltaics, in thin-film photovoltaics and in crystalline silicon modules. The laminates are used more particularly in photovoltaic modules. These may be either thick-film or thin-film photovoltaic modules. These modules may be either rigid or flexible. Application may also take place, furthermore, to the front, as an alternative to the preferred back. Alternatively, the film laminates developed may also find use in OLEDs, in displays or even in packaging films.

### WORKING EXAMPLES

### Example 1

### See FIG. 1

### Single-Layer, Filled PMMA Protective Layer

Protective layer: im-PMMA (layer thickness: 150 μm)+2% UV absorber CGX UVA 006+15% TiO₂

Layer2 of adhesive: Etimex Vistasolar 486

Production of protective layer by extrusion of the im-PMMA moulding composition filled with TiO₂ and with UV absorber. Lamination of the im-PMMA film to the substrate by means of the standard laminating process known to the skilled person, using Vistasolar film.

### Example 2

### See FIG. 2

### Two-Layer, Filled PMMA Protective Layer by Coextrusion

Protective layer: coextrudate of PVDF (layer thickness: 10 μm) and im-PMMA (layer thickness: 50 μm), the im-PMMA containing 1.5% UV absorber CGX UVA 006+10% TiO₂

Layer2 of adhesive: Etimex Vistasolar 486

Production of the protective layer by coextrusion of the PVDF moulding composition and im-PMMA moulding composition filled with TiO₂ and with UV absorber. Lamination of the im-PMMA film to the substrate by means of the standard lamination process known to the skilled person, using Vistasolar film

### Example 3

### See FIG. 3

### Two-Layer Filled Protective Layer by Adhesive Lamination

Layer 1a: im-PMMA (layer thickness: 50 μm)+2% UV absorber CGX UVA 006

Layer6 of adhesive: Bynel 22E780 (layer thickness: 40 μm) and

Layer 1b: PP Clyrell RC124H (layer thickness: 200 μm)+15% TiO₂

The protective layer is produced by coextrusion with layer3 of adhesive as adhesion promoter.

### Example 4

### See FIG. 4

### Laminate of Support Film, Barrier Layer and One-Layer PMMA Protective Layer

Protective layer: im-PMMA (layer thickness: 50 μm)

Layer of adhesive: two-component system Liofol LA 2692-21 and hardener UR 7395-22 from Henkel

Barrier layer: Al₂O₃, 40 nm

Support film: biaxially oriented PET (Hostaphan RNK, layer thickness 12 μm)

The barrier layer of aluminium oxide is applied to the support film by vacuum evaporation. This support film is laminated on to the protective layer, using the two-component system.

### Example 5

### See FIG. 5

### Laminate of Support Film, Barrier Layer and Two-Layer Protective Layer

Protective layer: coextrudate of PVDF (layer thickness: 10 μm) and im-PMMA (layer thickness: 50 μm), where the im-PMMA contains 1.5% UV absorber CGX UVA 006+10% TiO₂

Layer of adhesive: two-component system Liofol LA 2692-21 and hardener UR 7395-22 from Henkel

Barrier layer: SiOx, 30 nm

Support film: biaxially oriented PET (Hostaphan RNK, layer thickness 12 μm)

Layer2 of adhesive: Etimex Vistasolar 486

The barrier layer of SiOx is applied to the support film by vacuum evaporation. This support film is laminated on to the protective layer, using the two-component system. Subsequently, this film assembly is laminated to the substrate by means of the standard lamination process known to the skilled person, using Vistasolar film.

### EXPLANATIONS FOR THE APPENDED DRAWINGS

### List of Reference Symbols

1 Protective layer
2 Layer of adhesive
3 Support film
4 Barrier layer
5 Layer2 of adhesive
6 Layer3 of adhesive
1a PMMA layer of a two-layer film used as protective layer
1b Polyolefin, PET or PVDF layer of a two-layer film used as protective layer

### Explanations for the Individual Drawings

FIG. 1: pure protective layer with Layer2 of adhesive for joining to substrate (Example 1)

FIG. 2: protective layer comprising two-layer film with PVDF layer (Example 2)

FIG. 3: protective layer comprising two-layer film with adhesive Layer3 (Example 3)

FIG. 4: Backing film according to claim 3 (Example 4)

FIG. 5: Backing film according to claim 3 with protective layer comprising a two-layer film with PVDF layer (Example 5)

FIG. 6: protective layer comprising two-layer film with PET or polyolefin layer

FIG. 7: Backing film according to claim 3 with protective layer comprising a two-layer film with PET or polyolefin layer

Fillers are not shown. As described, according to the drawing, they are located in at least one of the layers 1, 1a, 1b, 2 or 3.

1. A non-transparent backing film comprising (i) a weathering-stable protective layer that comprises a polymethacrylate and has a thickness of between 50 and 1000 μm, and (ii) a filler.

2. The backing film of claim 1, further comprising
a) an optional adhesive layer,
b) an optional barrier layer, and
c) a support film,
wherein the filler is included in at least one selected from the group consisting of the protective layer, at least one layer of a two-layer protective layer, the adhesive layer, and the support film.

3. The backing film of claim 1, comprising, from an outside to an inside, the protective layer, an adhesive layer, a barrier layer and a support film.

4. The backing film of claim 1, wherein the protective layer is a PMMA film, a PMMA-PVDF blend film, or a film comprising a coextrudate of PMMA and a polyolefin or a polyester.

5. The backing film of claim 1, wherein the protective layer is a PMMA-polyolefin two-layer film, a PMMA-PET two-layer film, or a PMMA-PVDF two-layer film, wherein the PMMA layer may be a blend of PMMA with PVDF, PET or PP.

6. The backing film of claim 2, comprising the barrier layer, wherein the barrier layer comprises an inorganic oxide, and wherein the support film is a polyester or polyolefin film.

7. The backing film of claim 2, comprising the barrier layer, wherein the barrier layer is a metal layer, the filler is included in the support film, and the support film is a polyester or polyolefin film.

8. The backing film of claim 1, wherein the filler comprises inorganic particles.

9. The backing film of claim 7, wherein the filler is included in the support film in a concentration of between 1% and 30% by weight.

10. The backing film of claim 2, comprising the adhesive layer, wherein the adhesive layer comprises a melt adhesive selected from the group consisting of an ethylene-vinyl acetate copolymer, an ethylene-acrylate copolymer, and an ethylene-methacrylate copolymer.

11. The backing film of claim 2, comprising the adhesive layer, wherein the support film has a thickness of between 100 and 400 μm and the adhesive layer has a thickness of between 5 and 50 μm.

12. The backing film of claim 2, comprising the barrier layer, wherein the barrier layer is an SiO, layer having an x value of between 1.3 and 1.7 or is an AlOₓ layer having an x value of between 1.2 and 1.5, and the SiOₓ layer or the AlOₓ layer has a thickness of between 10 and 100 nm.

13. The backing film of claim 2, comprising the barrier layer, wherein the barrier layer is at least one metal layer having in each case a thickness of between 10 and 100 nm.

14. The backing film of claim 2, having a partial discharge voltage of at least 1000 V and a transparency of less than 10% in a wavelength range of 300-1200 nm.

15. A process for producing the backing film of claim 1, the process comprising
a) coating a polymer film with a barrier layer comprising an inorganic oxide, on one or both sides of the polymer film, by vacuum evaporation or sputtering, then applying a protective layer by lamination, extrusion lamination or extrusion coating, wherein at least one of the polymer film, barrier layer, and protective layer is filled with filler, and wherein the protective layer is a PMMA film, a PMMA-PVDF blend film, or a film comprising a coextrudate of PMMA and a polyolefin or a polyester; or
b) coating a polymer film with a metal barrier layer, on one or both sides of the polymer film, by vacuum evaporation or sputtering, then applying a protective layer by lamination, extrusion lamination or extrusion coating, wherein at least one of the polymer film, barrier layer, and protective layer is filled with filler, and wherein the protective layer is a PMMA film, a PMMA-PVDF blend film, or a film comprising a coextrudate of PMMA and a polyolefin or a polyester; or
c) coating a polymer film with a barrier layer comprising an inorganic oxide, on one or both sides of the polymer film, by vacuum evaporation or sputtering, and joining the coated polymer film by a layer of adhesive to a protective layer, wherein at least one of the polymer film, barrier layer, and protective layer is filled with filler, and wherein the protective layer is a PMMA film, a PMMA-PVDF blend film, or a film comprising a coextrudate of PMMA and a polyolefin or a polyester; or
d) coating a polymer film with a metal barrier layer, on one or both sides of the polymer film, by vacuum evaporation or sputtering, and joining the coated polymer film by a layer of adhesive to a protective layer, wherein at least one of the polymer film, barrier layer, and protective layer is filled with filler, and wherein the protective layer is a PMMA film, a PMMA-PVDF blend film, or a film comprising a coextrudate of PMMA and a polyolefin or a polyester,
wherein the vacuum evaporation in a) or c) comprises evaporating silicon oxide or aluminum oxide by an electron beam or by thermal evaporation.

16. An organic photovoltaic comprising the backing film of claim 1.

17. A thin-film photovoltaic comprising the backing film of claim 1.

18. A crystalline silicon module comprising the backing film of claim 1.

19. The backing film of claim 7, wherein the metal layer is an aluminum layer.

20. The backing film of claim 8, wherein the filler is included in the support film in a concentration of between 1% and 30% by weight.
